(19) United States
(12) Patent Application Publication
(10) Pub. No.: US 2026/0082771 A1
(43) Pub. Date: Mar. 19, 2026

(54) DISPLAY PANEL INCLUDING PIXEL DEFINING LAYER HAVING ELECTRODE OPENINGS AND ELECTRONIC DEVICE INCLUDING THE SAME

(71) Applicant: SAMSUNG DISPLAY CO., LTD., YONGIN-SI (KR)

(72) Inventors: DOGI LIM, Yongin-si (KR); DONGHYEON KI, Yongin-si (KR); KYUNGHOON PARK, Yongin-si (KR); SANGKYU PARK, Yongin-si (KR); SEONGYOUNG LEE, Yongin-si (KR); SEHO LEE, Yongin-si (KR); JUNGHO LEE, Yongin-si (KR)

(21) Appl. No.: 19/316,198

(22) Filed: Sep. 2, 2025

(30) Foreign Application Priority Data
Sep. 19, 2024 (KR) 10-2024-0126793

(51) Int. Cl. H10K 59/122; H10K 59/131

(52) U.S. Cl. CPC H10K 59/122; H10K 59/131

(57) ABSTRACT

A display panel includes a circuit layer including a power line connected to a power supply voltage, a lower insulating layer having a first opening exposing the power line, and an upper insulating layer having a second opening overlapping the first opening. A pixel defining layer includes an electrode opening and a light-emitting opening. A display layer includes a light-emitting element corresponding to the light-emitting opening and an electrode pattern corresponding to the electrode opening. The display panel electrically connects the power line, the electrode pattern, and the second electrode at a contact opening area where the first opening, the second opening, and the electrode opening overlap. The longest dimension of the second opening in a first direction is greater than the longest dimension of the electrode opening in the first direction, which may exhibit excellent electrical characteristics and reliability at high resolutions.

### CROSS-REFERENCE TO RELATED APPLICATIONS

This U.S. non-provisional patent application claims priority under 35 U.S.C. § 119 of Korean Patent Application No. 10-2024-0126793, filed on Sep. 19, 2024, the entire contents of which are hereby incorporated by reference.

### TECHNICAL FIELD

The present disclosure relates to a display panel and, more specifically, to a display panel including a pixel defining layer having electrode openings and an electronic device including the same.

### DISCUSSION OF THE RELATED ART

Multimedia electronic devices such as televisions, mobile phones, tablet computers, navigation systems, and portable game consoles utilize display panels for displaying images. These display panels may include a plurality of pixels. Each of the pixels may include a light-emitting element that produces light. A driving element is connected to the light-emitting element to provide control.

Display panels that incorporate light-emitting elements within the pixels offer several benefits such as a wide viewing angle, a fast response speed, and low power consumption. Thus, these emissive-type display panels are well suited for next-generation electronic devices. However, as the display panels included in electronic devices get larger and the display area increases, it becomes more difficult to provide a stable voltage across the entire area of the display panel, leading to a problem of luminance non-uniformity. Various structures may be relied upon to increase signal uniformity across larger display panels but the surface area occupied by these structures should be kept to a minimum.

### SUMMARY

A display panel includes a base layer and a circuit layer disposed on the base layer. The circuit layer includes a transistor, a power line connected to a power supply voltage, a lower insulating layer disposed on the power line and including a first opening, through which the power line is exposed, and an upper insulating layer disposed on the lower insulating layer and including a second opening overlapping the first opening. The display panel further includes display layer disposed on the circuit layer. The display layer includes a pixel defining layer including an electrode opening that overlaps the first and second openings and a light-emitting opening that does not overlap the electrode opening. A light-emitting element corresponds to the light-emitting opening. An electrode pattern corresponds to the electrode opening. The light-emitting element includes a first electrode disposed in the light-emitting opening, a light-emitting structure disposed on the first electrode, and a second electrode disposed on the light-emitting structure. The power line, the electrode pattern, and the second electrode are electrically connected to each other in a contact opening area in which the first opening, the second opening, and the electrode opening overlap. A width or longest dimension of the second opening in a first direction is greater than a width or longest dimension of the electrode opening in the first direction.

In the contact opening area, the electrode pattern may be disposed directly on the power line, and the second electrode may be disposed directly on the electrode pattern.

In a plan view, an edge of the upper insulating layer that defines the second opening may surround an edge of the pixel defining layer that defines the electrode opening.

The electrode pattern may be connected to the power line in the first opening and may extend from the first opening toward a side surface and a top surface of the upper insulating layer that defines the second opening.

The pixel defining layer that defines the electrode opening may cover the electrode pattern extending from the side surface of the upper insulating layer that defines the second opening.

A width or longest dimension of the first opening in the first direction may be less than a width or longest dimension of the electrode opening in the first direction.

The electrode pattern may include a first portion disposed in the first opening, a second portion extending from the first portion and disposed on a top surface of the lower insulating layer, a third portion extending from the second portion and disposed on a side surface of the upper insulating layer that defines the second opening, and a fourth portion extending from the third portion and disposed on a top surface of the upper insulating layer. The third portion, the fourth portion, and at least a part of the second portion may be covered by the pixel defining layer.

The second electrode may be in direct contact with the first portion of the electrode pattern and at least a part of the second portion, which is adjacent to the first portion, of the electrode pattern.

A width or longest dimension of the first opening in the first direction may be greater than a width or longest dimension of the electrode opening in the first direction and smaller than a width or longest dimension of the second opening in the first direction.

The electrode pattern may include a first portion that is in direct contact with the power line in the first opening, a second portion extending from the first portion and disposed on a side surface of the lower insulating layer, a third portion extending from the second portion and disposed on a top surface of the lower insulating layer, a fourth portion extending from the third portion and disposed on a side surface of the upper insulating layer that defines the second opening, and a fifth portion extending from the fourth portion and disposed on a top surface of the upper insulating layer. The second to fifth portions and at least a part of the first portion may be covered by the pixel defining layer.

The second electrode may be in direct contact with at least part of the first portion that is not covered by the pixel defining layer.

The electrode pattern may be disposed on a same layer as the first electrode, and the electrode pattern and the first electrode may be made of a same material.

The transistor may include a semiconductor pattern, and the semiconductor pattern and the power line may be disposed on a same layer.

The lower insulating layer may be an inorganic layer, and the upper insulating layer may be an organic layer.

The lower insulating layer may include silicon nitride, and the upper insulating layer may include polyimide.

An electronic device includes a display module divided into a plurality of pixel areas that each emit light having different wavelength ranges, and a non-pixel area that surrounds the plurality of pixel areas. The display module includes a display panel and a light control panel disposed on the display panel. A housing accommodates the display module. The display panel includes a base layer, a circuit layer having a power line disposed on the base layer in the non-pixel area, a lower insulating layer disposed on the power line and including a first opening through which the power line is exposed, an upper insulating layer disposed on the lower insulating layer and including a second opening overlapping the first opening, and a display layer disposed on the circuit layer. The display layer includes a pixel defining layer including an electrode opening that entirely overlaps the second opening, and a light-emitting opening that does not overlap the electrode opening. A light-emitting element corresponds to the light-emitting opening. An electrode pattern corresponds to the electrode opening. The light-emitting element includes a first electrode disposed in the light-emitting opening, a light-emitting structure disposed on the first electrode, and a second electrode disposed on the light-emitting structure. The power line, the electrode pattern, and the second electrode are electrically connected to each other in a contact opening area where the first opening, the second opening, and the electrode opening overlap one another. In a plan view, a surface area of the second opening is greater than that of the electrode opening.

In the plan view, an edge of the upper insulating layer that defines the second opening may surround an edge of the pixel defining layer that defines the electrode opening.

The power line may extend in a first direction on the base layer, and a plurality of contact opening areas may overlap the power line.

In each of the plurality of contact opening areas, the electrode pattern may be disposed directly on the power line, and the second electrode may be disposed directly on the electrode pattern.

The electrode pattern may extend from the first opening toward a side surface and a top surface of the upper insulating layer that defines the second opening, and the pixel defining layer that defines the electrode opening may cover the electrode pattern extending from the side surface of the upper insulating layer that defines the second opening.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an electronic device according to an embodiment;

FIG. 2 is an exploded perspective view of the electronic device according to an embodiment;

FIG. 3 is a cross-sectional view of a display module according to an embodiment;

FIG. 4 is a plan view of a display panel according to an embodiment;

FIG. 5 is an equivalent circuit diagram of a pixel according to an embodiment;

FIG. 6 is a plan view illustrating a portion of the display module according to an embodiment;

FIG. 7 is a cross-sectional view illustrating a portion of the display module according to an embodiment;

FIG. 8 is a cross-sectional view illustrating a portion of the display panel according to an embodiment;

FIG. 9 is a plan view illustrating a portion of the display module according to an embodiment;

FIG. 10 is a cross-sectional view of a display panel according to an embodiment;

FIG. 11 is a plan view illustrating a portion of the display module according to an embodiment;

FIG. 12 is a cross-sectional view illustrating a portion of the display module according to an embodiment;

FIG. 13 is a plan view illustrating a portion of the display module according to an embodiment;

FIG. 14 is a block diagram of an electronic device according to an embodiment; and

FIG. 15 illustrates schematic views of an electronic device according to an embodiment.

### DETAILED DESCRIPTION

Since the present disclosure may have diverse modified embodiments, specific embodiments are illustrated in the drawings and are described in the detailed description of the inventive concept. However, this does not necessarily limit the present disclosure within specific embodiments and it should be understood that the present disclosure covers all the modifications, equivalents, and replacements within the idea and technical scope of the present disclosure.

In this specification, it will also be understood that when one component (or region, layer, portion) is referred to as being ‘on’, ‘connected to’, or ‘coupled to’ another component, it can be disposed directly on/connected to/coupled to the other component, or an intervening third component may also be present.

Like reference numerals may refer to like elements throughout the specification and the drawings. Also, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. The term “and/or” includes any and all combinations of one or more of the associated components.

It will be understood that although the terms such as ‘first’ and ‘second’ are used herein to describe various elements, these elements should not necessarily be limited by these terms. The terms are used for the purpose of distinguishing one component from another. For example, a first element referred to as a first element in an embodiment can be referred to as a second element in another embodiment without departing from the scope of the appended claims. The singular forms include the plural forms as well, unless the context clearly indicates otherwise.

Also, “under”, “below”, “above”, “upper”, and the like are used for explaining relation association of components illustrated in the drawings. The terms may be a relative concept and described based on directions expressed in the drawings.

It will be understood that the term “include” or “comprise”, when used in this specification, specifies the presence of stated features, integers, steps, operations, elements, components, or a combination thereof, but does not necessarily preclude the presence or addition of one or more other features, integers, steps, operations, elements, components, or combinations thereof.

In this specification, “disposed directly” may mean that there is no layer, film, region, plate, or the like between a portion of the layer, the layer, the region, the plate, or the like and the other portion. For example, “disposed directly” may mean being disposed without using an additional member such and an adhesion member between two layers or two constituent elements.

In this specification, that “area/portion and area/portion corresponds to each other” means “overlapping each other”, but is not necessarily limited to that have the same area and/or the same shape. Additionally, in this specification, where it is said that a first area or part overlaps a second area or part, this means that the first and second area or part overlap one another on a plane, at least partially.

Embodiments of the present disclosure center on a compact and efficient structural design for a display panel that improves voltage stability and reduces luminance non-uniformity, especially in high-resolution, large-area displays, by optimizing the electrical connection between the cathode of the light-emitting element and the power supply line. Traditional designs required multiple distinct connection areas for routing power through auxiliary electrodes, which took up valuable non-emissive space. Embodiments of the present invention simplify the structure by enabling both the cathode-to-auxiliary electrode connection and the auxiliary-to-power line connection within a single integrated contact opening area.

This may be achieved through a layered architecture involving a base substrate, a circuit layer, and a display layer. In the circuit layer, a power line is embedded beneath a lower inorganic insulating layer, which includes a first opening. An upper organic insulating layer above it includes a second, wider opening that overlaps the first. A pixel defining layer in the display layer defines a third opening, which is narrower than the second opening. An electrode pattern, which serves as the auxiliary electrode, spans from the exposed power line upward through these layers and connects to the cathode. The overlap of these three openings, forming a contact opening area, enables direct electrical continuity in a vertical stack without requiring horizontal spreading of the components.

Embodiments of the present invention provide a dimensional hierarchy of the openings in which the second opening in the upper insulating layer is wider than the third opening in the pixel defining layer. This configuration allows the pixel defining material to partially encapsulate and protect the exposed edges of the underlying insulating layers and the electrode pattern itself, enhancing durability and fabrication reliability.

Thus, embodiments of the present invention provide a display panel that achieves a more compact and reliable connection scheme, enabling higher pixel densities and better uniformity across large screen areas while conserving space in the non-emissive regions. This reflects a design innovation rooted in maximizing efficiency and manufacturability for next-generation display technologies.

Hereinafter, a display device according to one embodiment of the inventive concept and an electronic device including the same will be described with reference to the drawings.

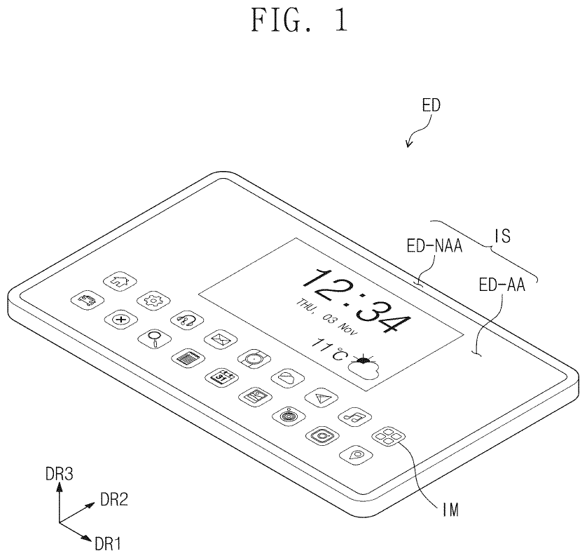

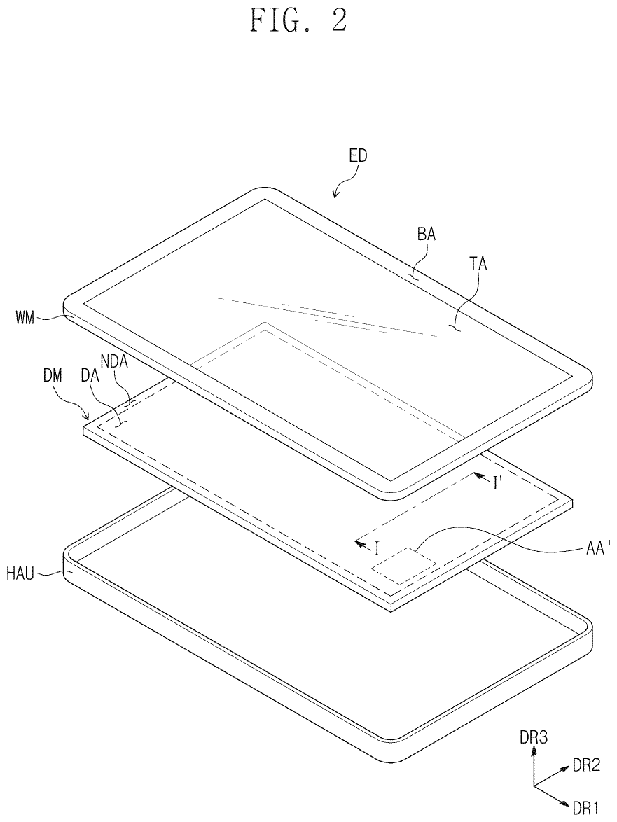

FIG. 1 is a perspective view of an electronic device according to an embodiment. FIG. 2 is an exploded perspective view of the electronic device according to an embodiment.

The electronic device ED, according to one embodiment, which is activated in response to an electrical signal, may be a display device for displaying images. The electronic device ED may include various embodiments. For example, the electronic device ED may include large-scale devices, such as televisions and digital billboards, and small-to-medium devices, such as computer monitors, mobile phones, tablet computers, navigation units, and portable game consoles. Here, the embodiments of the electronic device ED are examples, and are not necessarily limited to any one example as long as not departing from the inventive concept.

Here, in FIG. 1 and the following drawings, first direction axis DR1, the second direction axis DR2, and the third direction axis DR3 are illustrated. The directions indicated as the first to third direction axes DR1, DR2, and DR3 illustrated herein may have a relative concept and thus be changed to other directions. The directions indicated as the first to third direction axes DR1, DR2, and DR3 may be referred to as first to third directions, and the same reference symbols may be used.

The thickness direction of the electronic device ED may be in the third direction axis DR3 which is a normal direction to the plane defined by the first direction axis DR1 and the second direction axis DR2. In this specification, a front surface (or a top surface) and a rear surface (or a bottom surface) of each element constituting the electronic device ED may be defined with respect to the third direction axis DR3.

The electronic device ED may display an image IM in a third direction DR3 through a display surface IS in a plane defined by the first direction DR1 and the second direction DR2. The third direction DR3 may be the normal direction of the display surface IS. The display surface IS on which the image IM is displayed may correspond to a front surface of the electronic device ED. The image IM may include a still image as well as a dynamic image. FIG. 1 illustrates icon images as an example of the image IM.

As used herein, the expression of “in a plan view” may be defined as a state when viewed in the third direction DR3. As used herein, the expression of “in a cross-sectional view” may be defined as a state when viewed in the first direction DR1 or the second direction DR2. Here, directions indicated as the first to third directions DR1, DR2, and DR3 may have a relative concept and thus may be changed to other directions.

In FIG. 1, an electronic device ED having a planar display surface IS is illustrated as an example. However, the shape of the display surface IS of the electronic device ED is not necessarily limited thereto and may be curved or three-dimensional.

The electronic device ED may be flexible. The term “flexible” indicates a property of being bendable to at least an appreciable degree, without cracking or otherwise sustaining damage, and may encompass all structures from a completely foldable structure to a structure bendable to a several-nanometer. For example, the flexible electronic device ED may be a curved electronic device (e.g., a device that has a fixed curvature) or a foldable electronic device (e.g., a device that may be repeatedly folded and unfolded).

The display surface IS of the electronic device ED may include an active area ED-AA and a peripheral area ED-NAA. The user may view an image IM through the active area ED-AA. In the embodiment shown in FIG. 1 and others, the active area ED-AA is depicted as having a substantially rectangular shape, but this is an example, and the active area ED-AA may have various shapes.

The peripheral area ED-NAA may be a non-display portion that does not show the image IM. The peripheral area ED-NAA may have a predetermined color and may function as a light-blocking portion. The peripheral area ED-NAA may be adjacent to the active area ED-AA. For example, the peripheral area ED-NAA may be disposed on an outer edge of at least one side of the active area ED-AA and surround the active area ED-AA. However, this is merely an example, and the peripheral area ED-NAA may be adjacent to only one side of the active area ED-AA, or it may be disposed on a side surface rather than a front surface of the electronic device ED. Furthermore, it is not necessarily limited thereto, and the peripheral area ED-NAA may be omitted.

Also, the peripheral area ED-NAA, according to an embodiment, may detect an external input. Additionally, the external input may include various types such as force, pressure, temperature, or light. The external input may include not only input that involving contact with the electronic device ED (for example, contact by the user's hand or a stylus/pen), but also input applied in proximity to the electronic device ED (for example, hovering).

Referring to FIG. 2, the electronic device ED may include a window WM, a display module DM, and a housing HAU. The window WM and the housing HAU may be coupled to each other, together defining an outer shell of the electronic device ED and providing an internal space in which components such as a display module DM are accommodated.

The window WM may be disposed on the display module DM. The window WM may protect the display module DM from external impact. A front surface of the window WM may correspond to the display surface IS of the electronic device ED described above. The front surface of the window WM may include a transmission area TA, through which visible light may pass, and a bezel area BA, through which visible light is blocked.

The transmission area TA of the window WM may be an optically transparent area. The window WM may transmit the image provided by the display module DM through the transmission area TA, allowing the user to view the relevant image. The transmission area TA may correspond to the active area ED-AA of the electronic device ED.

The window WM may include an optically transparent insulation material. For example, the window WM may include glass, sapphire, or a polymer. The window WM may have a single-layered or multi-layered structure. The window WM may further include various functional layers such as an anti-fingerprint layer, a phase control layer, and a hard coating layer, which are disposed on an optically transparent substrate.

The bezel area BA of the window WM may be an area on which a material having a predetermined color is deposited, coated, or printed. The bezel area BA of the window WM may prevent a component of the display module DM overlapping the bezel area BA, from being visible externally and may prevent light from entering the device therethrough. The bezel area BA may correspond to the peripheral area ED-NAA of the electronic device ED.

The display module DM may display an image in response to the electrical signal. The display module DM may include a display area DA and a non-display area NDA, which is adjacent to (and may at least partially surround) the display area DA.

The display area DA may correspond to the active area ED-AA of the electronic device ED. The display area DA may be an area that is activated in response to the electrical signal. The display area DA may be an area through which the image provided from the display module DM is emitted. The display area DA of the display module DM may correspond to the transmission area TA. In this specification, where it is said that a first area or portion corresponds to a second area or portion, this means that the first and second area or portions overlap one another, but is not necessarily limited to that have the same area and/or the same shape. The image displayed on the display area DA may be viewed from the outside through the transmission area TA.

The non-display area NDA may be adjacent to the display area DA. For example, the non-display area NDA may surround the display area DA on two or more sides thereof. However, the embodiment of the inventive concept is not necessarily limited thereto, and the non-display area NDA may be defined as various shapes. The non-display area NDA may correspond to the peripheral area ED-NAA of the electronic device ED. The non-display area NDA may be an area in which a driving circuit for driving the display area DA, various signal lines providing electrical signals, and pads are arranged. The non-display area NDA of the display module DM may correspond to the above-described bezel area BA. Components of the display module DM disposed in the non-display area NDA may be prevented from being visible externally by the bezel area BA.

The housing HAU may be disposed below the display module DM to accommodate the display module DM. The housing HAU may absorb external impact and prevent foreign substances/moisture from penetrating into the display module DM, thereby protecting the display module DM. The housing HAU, according to an embodiment, may be a structure in which a plurality of accommodation members are coupled to each other.

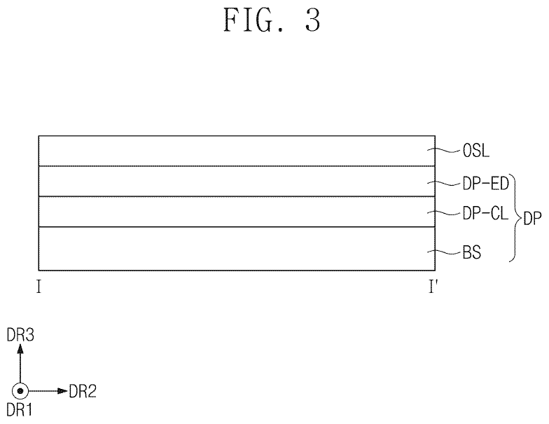

FIG. 3 is a cross-sectional view of the display module according to an embodiment. FIG. 3 may be a cross-sectional view of a portion corresponding to line I-I′ of FIG. 2.

The display module DM, according to an embodiment, may include a display panel DP. The display panel DP may include a base layer BS, a circuit layer DP-CL, and a display layer DP-ED, which are sequentially stacked in the third axis direction DR3. In addition, the display module DM, according to an embodiment, may further include a light control panel OSL disposed on the display panel DP. The light control panel OSL may be disposed on the display layer DP-ED.

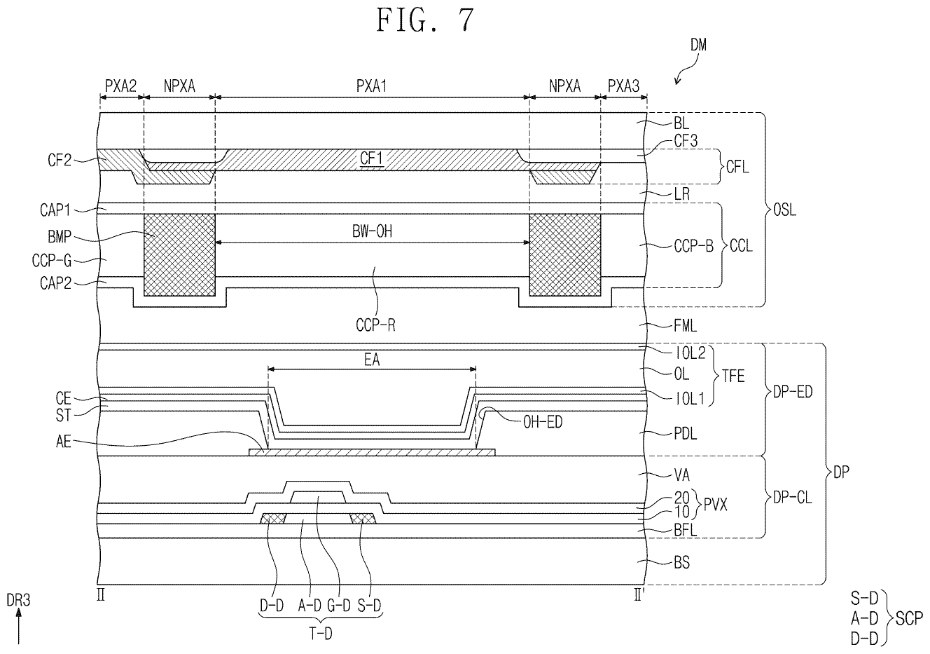

In one embodiment, a filling layer FML (see FIG. 7) may be disposed between the display panel DP and the light control panel OSL. The display panel DP and the light control panel OSL may be spaced apart from each other with the filling layer FML (see FIG. 7) interposed in between. In this case, the light control panel OSL may be provided on the display panel DP after being manufactured in a separate process step.

Additionally, in the display module DM, according to an embodiment, the light control panel OSL may be disposed directly on the display layer DP-ED. In this specification, the term “disposed directly” on another component means that no third component is disposed between a component and another component. For example, when one component is “disposed directly” on another component, the two components are in contact with each other.

In one embodiment, the base layer BS may be a support substrate on which the circuit layer DP-CL and the display layer DP-ED are provided. In one embodiment, the base layer BS of the display panel DP may provide a reference surface on which components included in the circuit layer DP-CL are disposed. In one embodiment, the base layer BS may include a glass substrate, a metal substrate, a polymer substrate, or similar.

In one embodiment, the base layer BS may be an inorganic layer, a functional layer, or a composite material layer. The base layer BS may have a multilayer structure. For example, the base layer BS may have a three-layer structure consisting of a polymer resin layer, an adhesive layer, and another polymer resin layer. In particular, the polymer resin layer may include polyamide-based resin.

The circuit layer DP-CL may include at least one insulating layer, a circuit element, a power line, and a pad, etc. The circuit element includes a signal line, a driving circuit of a pixel, and the like. The circuit layer DP-CL may be provided through a process of forming an insulating layer, a semiconductor layer, and a conductive layer using coating, deposition, or the like and a process of pattering the insulating layer, the semiconductor layer, and the conductive layer using a photolithography process.

The display layer DP-ED includes a display element. The display element may include a light-emitting element that generates light and provides the light to the light control panel OSL. The display panel DP including the display layer DP-ED may provide source light to the light control panel OSL disposed thereon.

The light control panel OSL may convert a wavelength of the light provided by the display panel DP or transmit a portion of the provided light. The light control panel OSL may include a light control part that converts or transmits the wavelength, and components to increase conversion efficiency of emitted light.

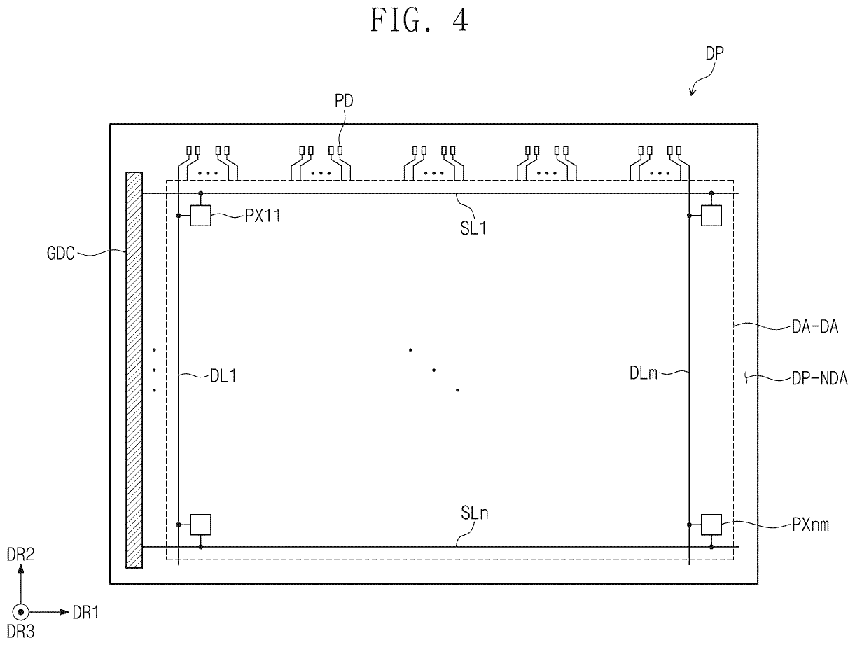

FIG. 4 is a plan view of a display panel according to an embodiment.

Referring to FIG. 4, a display panel DP may include a display area DP-DA and a non-display area DP-NDA. The display area DP-DA may correspond to the active area ED-AA of the electronic device ED (see FIG. 1), and the non-display area DP-NDA may correspond to the peripheral area ED-NAA of the electronic device ED (see FIG. 1). The non-display area DP-NDA may surround the display area DP-DA on at least two sides thereof. However, the embodiment is not necessarily limited thereto, in one embodiment of the inventive concept, the non-display area DP-NDA may be omitted or only disposed on one side of the display area DP-DA.

FIG. 4 illustrates arrangement of signal lines SL1 to SLn and DL1 to DLm, and pixels PX11 to PXnm on a plane. As used herein, “n” and “m” may be positive integers. The pixels PX11 to PXnm may be disposed in the display area DP-DA, and a driving circuit GDC and pads PD may be disposed in the non-display area DP-NDA. The signal lines SL1 to SLn and DL1 to DLm may be electrically connected to the pixels PX11 to PXnm, and may be connected to the driving circuit GDC or the pads PD.

The signal lines SL1 to SLn and DL1 to DLm may include a plurality of scan lines SL1 to SLn and a plurality of data lines DL1 to DLm. Each of the pixels PX11 to PXnm may be connected to a corresponding scan line among the plurality of scan lines SL1 to SLn and a corresponding data line among the plurality of data lines DL1 to DLm. Each of the pixels PX11 to PXnm may include a pixel driving circuit and the display element. A wider variety of signal lines may be provided in the display panel DP, depending on the configuration of the pixel driving circuits of the pixels PX11 to PXnm.

The driving circuit GDC may include a gate driving circuit. The gate driving circuit may generate a gate signal and sequentially output the gate signal to the scan lines SL1 to SLn. The gate driving circuit may further output another control signal to the pixel driving circuit of each of the pixels PX11 to PXnm.

The driving circuit GDC may be integrated on the display panel DP by an oxide silicon gate (OSG) driver circuit process or an amorphous silicon gate (ASG) driver circuit process.

The pads PD may be arranged on the non-display are NDA in one direction. The pads PD may serve as parts that connect to a separate circuit board. Each of the pads PD may be connected to a corresponding signal line among the plurality of signal lines SL1 to SLn and DL1 to DLm and electrically connected to a corresponding pixel through the signal line. The pads PD may have an integral shape with signal lines SL1 to SLn and DL1 to DLm. However, the embodiment is not necessarily limited thereto, and the pads PD may be disposed on a different layer from the signal lines SL1 to SLn and DL1 to DLm, and may be connected through contact holes.

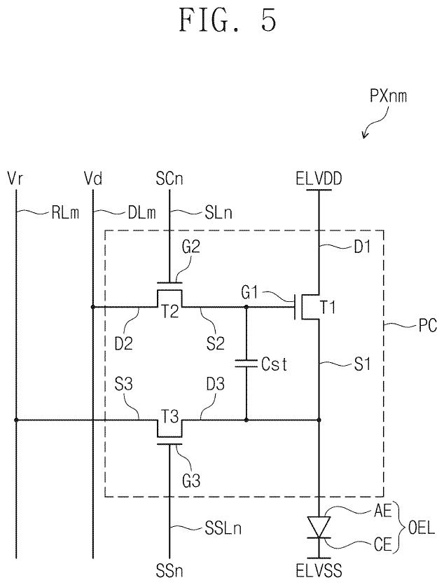

FIG. 5 is an equivalent circuit diagram of the pixel according to an embodiment.

FIG. 5 illustrates an example of a pixel PXnm connected to an n-th scan line SLn, an n-th sensing line SSLn, an m-th data line DLm, and an m-th reference line RLm. Referring to FIG. 5, the pixel PXnm may include a pixel circuit PC and a light-emitting element OEL connected to the pixel circuit PC.

The pixel circuit PC may include a plurality of transistors T1, T2, and T3 and a capacitor Cst. The plurality of transistors T1, T2, and T3 may include a first transistor T1 (or a driving transistor), a second transistor T2 (or a switching transistor), and a third transistor T3 (or a sensing transistor). Each of the first to third transistors T1, T2, and T3 may be a thin-film transistor.

The first to third transistors T1, T2, and T3 may be NMOS transistors, but the embodiment is not necessarily limited thereto, and the first to third transistors T1, T2, and T3 may be PMOS transistors. The first to third transistors T1, T2, and T3 may include sources S1, S2, and S3, drains D1, D2, and D3, and gates G1, G2, and G3, respectively.

The light emitting element OEL may be an organic light-emitting element including a first electrode AE and a second electrode CE. The first electrode AE may be referred to as an anode. The second electrode CE may be referred to as a cathode. The first electrode AE may receive a first power supply voltage ELVDD through the driving transistor T1, and the second electrode CE may receive a second power supply voltage ELVSS. The light emitting element OEL may receive the first power supply voltage ELVDD and the second power supply voltage ELVSS to emit light.

The driving transistor T1 may include a drain D1 that receives the first power supply voltage ELVDD, a source S1 connected to the first electrode AE, and a gate G1 connected to the capacitor Cst. The driving transistor T1 may control driving current flowing through the light emitting element OEL from the first power supply voltage ELVDD in response to a voltage value stored in the capacitor Cst.

The switching transistor T2 may include a drain D2 connected to the m-th data line DLm, a source S2 connected to the capacitor Cst, and a gate G2 that receives an n-th write scan signal SCn. The m-th data line DLm may receive a data voltage Vd and a sensing data voltage. The switching transistor T2 may transfer the data voltage Vd inputted from the m-th data line DLm to the driving transistor T1, according to a switching voltage inputted from the n-th write scan signal SCn.

The sensing transistor T3 may include a source S3 connected to the m-th reference line RLm, a drain D3 connected to the first electrode AE, and a gate G3 that receives an n-th sampling scan signal SSn. The m-th reference line RLm may receive a reference voltage Vr.

The capacitor Cst may be connected to the gate G1 of the driving transistor T1 and the first electrode AE. The capacitor Cst may include a first capacitor electrode connected to the gate G1 of the driving transistor T1 and a second capacitor electrode connected to the first electrode AE. The capacitor Cst may store a voltage that corresponds to a difference between the voltage received from the switching transistor T2 and the first power supply voltage ELVDD.

The equivalent circuit diagram of the pixel PXnm is not necessarily limited to the equivalent circuit diagram shown in FIG. 5. In an embodiment of the inventive concept, the equivalent circuit diagram of the pixel PXnm may be implemented in various structures to emit light from the light-emitting element OEL.

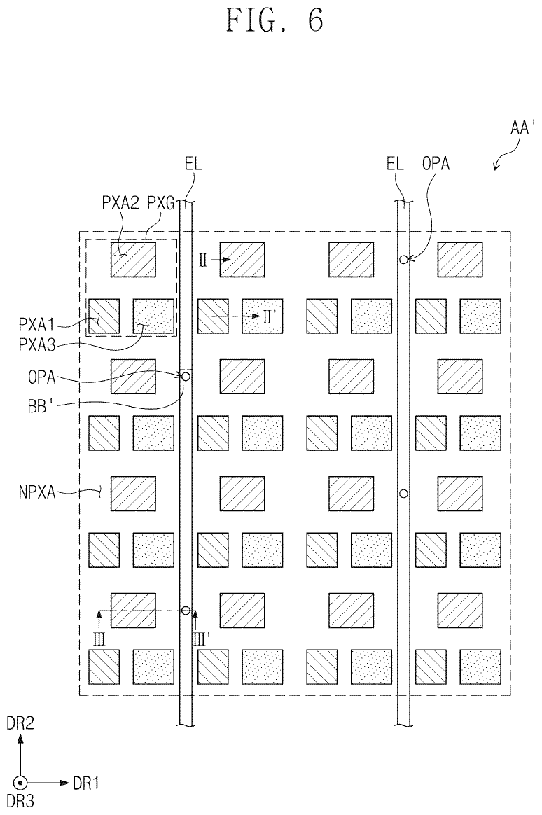

FIG. 6 is a plan view of a portion of the display module according to an embodiment. FIG. 6 is an enlarged plan view illustrating a portion AA′ of FIG. 2.

FIG. 6 illustrates arrangement of a plurality of pixel areas PXA1, PXA2, and PXA3 disposed in the display area DA (see FIG. 2) according to an embodiment. Each of the pixel areas PXA1, PXA2, and PXA3 may correspond one-to-one with the pixels PX11 to PXnm (see FIG. 4) and may be an area in which light generated from the pixels PX11 to PXnm (see FIG. 4) is emitted externally. For example, the light generated by the pixel is emitted from the light-emitting element OEL. The pixel areas PXA1, PXA2, and PXA3 may be defined by separate areas of the light control panel OSL. In one embodiment, the three types of pixel areas PXA1, PXA2, and PXA3 shown in FIG. 6 may be repeatedly arranged across the entire display area DA (see FIG. 2).

In one embodiment, the display module may include a first pixel area PXA1, a second pixel area PXA2, and a third pixel area PXA3, which emit light of different wavelength ranges. The first to third pixel areas PXA1, PXA2, and PXA3 may be separated from each other without overlapping one another in a plan view. The pixel areas PXA1, PXA2, and PXA3 may be referred to as light-emitting areas. The first to third pixel areas PXA1, PXA2, and PXA3 may be referred to as first to third light-emitting areas, respectively.

The first pixel area PXA1 may emit light with an emission wavelength of approximately 610 nm to 700 nm, the second pixel area PXA2 may emit light with an emission wavelength of approximately 500 nm to 590 nm, and the third pixel area PXA3 may emit light with an emission wavelength of approximately 410 nm to 480 nm.

In one embodiment, the first pixel area PXA1 may be a red pixel area through which red light is emitted, the second pixel area PXA2 may be a green pixel area through which green light is emitted, and the third pixel area PXA3 may be a blue pixel area through which blue light is emitted. However, the embodiment is not necessarily limited thereto, and in one embodiment, the display area DA (see FIG. 2) may further include a pixel area through which white light is emitted, in addition to the first to third pixel areas PXA1, PXA2, and PXA3.

In one embodiment, a pixel unit PXG may be configured by grouping one first pixel area PXA1, one second pixel area PXA2, and one third pixel area PXA3. The arrangement of pixel areas shown in FIG. 6 is an example, and one pixel unit PXG may further include a pixel area through which light of different wavelength range is emitted, in addition to the first to third pixel areas PXA1, PXA2, and PXA3. Additionally, the pixel unit PXG may include at least two of the first to third pixel areas PXA1, PXA2, and PXA3.

A non-pixel area NPXA may be disposed beyond the first to third pixel areas PXA1, PXA2, and PXA3. The non-pixel area NPXA may surround each of the first pixel area PXA1, second pixel area PXA2, and third pixel area PXA3. The non-pixel area NPXA may determine boundaries between the first to third pixel areas PXA1, PXA2, and PXA3 and prevent color mixing between the first to third pixel areas PXA1, PXA2, and PXA3. A structure for preventing color mixing between the first to third pixel areas PXA1, PXA2, and PXA3, for example, a pixel defining layer PDL (see FIG. 7) or a division pattern BMP (see FIG. 7), may be disposed in the non-pixel area NPXA. The non-pixel area NPXA may be referred to as a non-emission area.

FIG. 6 illustrates an example of the first to third pixel areas PXA1, PXA2, and PXA3, which have similar rectangular shapes in a plan view but differ in surface areas, but the embodiment is not necessarily limited thereto. Two or more pixel areas among the first to third pixel areas PXA1, PXA2, and PXA3 may have the same surface area. The surface areas of the first to third pixel areas PXA1, PXA2, and PXA3 may be set according to emitted color. The size of each pixel area may be adjusted according to the color characteristics required by the display module DM.

In FIG. 6, the first to third pixel areas PXA1, PXA2, PXA3 are illustrated as rectangular shapes; however, the embodiment is not necessarily limited thereto. In a plan view, the first to third pixel areas PXA1, PXA2, and PXA3 may have polygonal shapes, such as a rhombus or pentagon (including substantially polygonal shapes). In one embodiment, the first to third pixel areas PXA1, PXA2, and PXA3 may have substantially rectangular shapes with rounded corners in a plan view.

FIG. 6 shows that the second pixel area PXA2 is disposed in a first row, while the first pixel area PXA1 and the third pixel area PXA3 are disposed in a second row; however, the arrangement of the first to third pixel areas PXA1, PXA2, and PXA3 is not necessarily limited thereto and may be varied. For example, the first to third pixel areas PXA1, PXA2, and PXA3 may be disposed in the same row.

Referring to FIG. 6, the display module DM, according to an embodiment, may include a power line EL. The power line EL may be disposed in the non-pixel area NPXA. The power line EL may be disposed in an extending shape in one direction. The power line EL may be disposed on the base layer BS (see FIG. 3) and a portion to which the second power supply voltage ELVSS (see FIG. 5) is applied.

FIG. 6 illustrates that the power line EL is disposed between the pixel units PXG in a manner extending in the second direction DR2. However, the embodiment is not necessarily limited thereto, and the power line EL may have a line shape extending primarily in the first direction DR1 or a grid shape surrounding one of the pixel areas PXA1, PXA2, and PXA3. As used herein, the phrase “extending primarily in a given direction” means that the element, which may be a two or three-dimensional structure that extends to some degree in multiple directions, has a largest direction of extension in the given direction. The power line EL may have various shapes without necessarily being limited to any one embodiment when it is able to supply the power supply voltage to each of the pixels PX1 to PXnm (see FIG. 4).

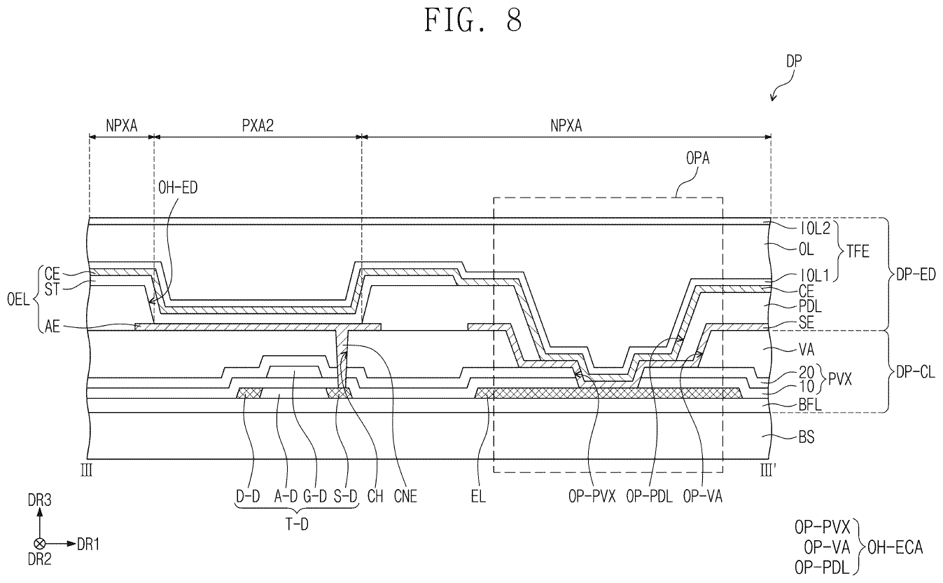

The display module, according to an embodiment, may include a plurality of opening areas OPA overlapping the power line EL. The power line EL and the second electrode CE (see FIG. 8) may be electrically connected to each other in the opening areas OPA. In the opening areas OPA, the power line EL and the second electrode CE (see FIG. 8) may be electrically connected to each other through an electrode pattern SE.

Arrangement of the opening areas OPA is not necessarily limited to what is illustrated. The number and arrangement of the opening areas OPA may be adjusted in consideration of the arrangement of the power lines EL, the arrangement of the pixels PX1 to PXnm (see FIG. 4), the resolution of the display panel, or the effect of voltage drop. Additionally, the number and arrangement of the opening areas OPA may be adjusted in consideration of the performance of the laser irradiation device used to remove a portion of layers of the light-emitting element OEL by laser drilling, as well as the cost-effectiveness of the laser drilling process.

FIG. 7 illustrates a cross-sectional view of a portion of the display module according to an embodiment, and FIG. 8 illustrates a cross-sectional view of a portion of the display panel according to an embodiment. FIG. 7 may be a cross-sectional view corresponding to line II-II′ of FIG. 6. FIG. 8 may be a cross-sectional view illustrating a portion corresponding to line III-III′ of FIG. 6, showing a portion corresponding to the display panel.

Referring to FIG. 7, a display module DM may include a display panel DP and a light control panel OSL disposed on the display panel DP. In one embodiment, a filling layer FML may be disposed between the display panel DP and the light control panel OSL.

The filling layer FML may serve as a buffer between the display panel DP and the light control panel OSL. In one embodiment, the filling layer FML may provide impact absorption and increase the strength of the display module DM. The filling layer FML may be made of a filling resin including a polymer resin. However, this is merely an example. A structure of the display module according to an embodiment is not necessarily limited thereto. In one embodiment, the filling layer FML may be omitted, and the light control panel OSL may be disposed directly on the display panel DP or provided such that a gap is maintained between the display panel DP and the light control panel OSL without filling.

In one embodiment, the display panel DP may include a base layer BS, a circuit layer DP-CL disposed on the base layer BS, and a display layer DP-ED disposed on the circuit layer DP-CL. Additionally, the display layer DP-ED may include a pixel defining layer PDL, a light-emitting element OEL, an encapsulation layer TFE, and an electrode pattern SE. The electrode pattern SE may be disposed between the second electrode CE of the light-emitting element OEL and the power line EL of the circuit layer DP-CL. The electrode pattern SE connects the second electrode CE and the power line EL to each other, and may be referred to as an auxiliary electrode.

The display panel DP may be a light emission-type display panel. For example, the display panel DP may be an organic electroluminescence display panel. When the display panel DP is an organic electroluminescent display panel, the display layer DP-ED may include an organic electroluminescent element as the light-emitting element OEL. However, the embodiment is not necessarily limited thereto. For example, the display layer DP-ED may include a quantum dot light-emitting element as the light-emitting element OEL. Additionally, the display layer DP-ED may include a micro LED element and/or a nano LED element, as the light-emitting element OEL.

The display panel DP may provide source light. The light-emitting element OEL may generate the source light. The source light generated and output from the light-emitting element OEL may be provided to the light control panel OSL. At least a portion of the source light may be optically converted into light with a wavelength different from that of the source light in a light control layer CCL of the light control panel OSL, or at least a portion of the source light may be transmitted without wavelength conversion.

In the display panel DP, the base layer BS may be a member that provides a reference surface on which the components provided in the circuit layer DP-CL are disposed.

The circuit layer DP-CL may include a plurality of circuit elements and a plurality of insulating layers. Additionally, the circuit layer DP-CL may include a plurality of signal lines and a plurality of power lines. The circuit layer DP-CL may include a transistor T-D as a circuit element. The configuration of the circuit layer DP-CL may vary depending on the design of the driving circuit for the pixel PXnm (see FIG. 5), and FIGS. 7 and 8 show a single transistor T-D. The transistor T-D shown in FIGS. 7 and 8 may be a driving transistor. The transistor T-D shown in FIGS. 7 and 8 may be referred to as the first transistor T1 (see FIG. 5).

FIGS. 7 and 8 show arrangement of a semiconductor pattern SCP and a gate G-D, which constitute the transistor T-D. The semiconductor pattern SCP may be divided into a source S-D, an active A-D, and a drain D-D. Arrangement of the active A-D, the source S-D, the drain D-D, and gate G-D is shown. The source S-D, the active A-D, and the drain D-D may be areas differentiated based on doping concentration or conductivity of the semiconductor pattern SCP.

The circuit layer DP-CL may include a buffer layer BFL, a lower insulating layer PVX, and an upper insulating layer VA disposed on the base layer BS. The lower insulating layer PVX may include a first insulating layer 10 and a second insulating layer 20. In the circuit layer DP-CL, the buffer layer BFL, the first insulating layer 10, and the second insulating layer 20 may be inorganic layers, while the upper insulating layer VA may be an organic layer.

The buffer layer BFL may serve as a barrier layer that protects a bottom surface of each of the active A-D, the source S-D, and the drain D-D. The buffer layer BFL may block contaminants or moisture entering through the base layer BS itself or penetrating into the semiconductor pattern SCP through the base layer BS. Alternatively, the buffer layer BFL may function as a light-blocking layer that prevents external light incident through the base layer BS from entering the active A-D. In this case, the buffer layer BFL may further include a light-blocking material.

The first insulating layer 10 may be disposed on the buffer layer BFL and may cover the semiconductor pattern SCP. The gate G-D may be disposed on the first insulating layer 10. The second insulating layer 20 may be disposed on the first insulating layer 10 and may cover the gate G-D.

The first insulating layer 10 and the second insulating layer 20 may be referred to as the lower insulating layer PVX. Each of the first insulating layer 10 and the second insulating layer 20 may be an inorganic layer including an inorganic material. Each of the first insulating layer 10 and the second insulating layer 20 may independently be a single layer or a plurality of layers. Each of the first insulating layer 10 and the second insulating layer 20 may independently include at least one of silicon nitride, silicon oxynitride, silicon oxide, titanium oxide, or aluminum oxide. For example, each of the first insulating layer 10 and the second insulating layer 20 may include silicon nitride.

The upper insulating layer VA may be disposed on the second insulating layer 20. The upper insulating layer VA may be a single layer or a plurality of layers. The upper insulating layer VA may include an organic layer formed of an organic material. The upper insulating layer VA may be a flattened layer that provides a flat surface on an upper portion of the circuit layer DP-CL.

A second opening OP-VA may be defined in the upper insulating layer VA. The second opening OP-VA may be defined as overlapping with a first opening OP-PVX.

The circuit layer DP-CL may include the power line EL. The power line EL may be disposed on the same layer as the semiconductor pattern SCP. The power line EL may be disposed on the buffer layer BFL. A portion of a top surface of the power line EL may be exposed by the first opening OP-PVX defined in the lower insulating layer PVX. The power line EL may be provided in the same process step in a process of forming the semiconductor pattern SCP.

The display layer DP-ED may be disposed on the upper insulating layer VA. The display layer DP-ED may include the light-emitting element OEL as a display element. In one embodiment, the light-emitting element OEL may be disposed on the upper insulating layer VA. The light-emitting element OEL may generate the source light.

For example, in one embodiment, the source light provided by the light-emitting element OEL may be light in a blue wavelength range. Additionally, the source light provided by the light-emitting element OEL may include source light in both the blue and green wavelength ranges.

The light-emitting element OEL includes the first electrode AE, the second electrode CE facing the first electrode AE, and a light-emitting structure ST disposed between the first electrode AE and the second electrode CE. The light-emitting element OEL may further include a capping layer disposed on the second electrode CE.

The light-emitting structure ST may include a light-emitting unit with a stacked structure having a hole transport layer (HTL), a light-emitting layer, and an electron transport layer (ETL). The light-emitting structure ST may include a single light-emitting unit or a plurality of light-emitting units stacked in a thickness direction. The light-emitting element OEL including the light-emitting structure ST in which a plurality of light-emitting units are stacked may be a tandem light-emitting element, which includes a plurality of light-emitting layers stacked in the thickness direction.

The first electrode AE of the light-emitting element OEL may be connected directly or indirectly to the transistor T-D. Referring to FIG. 8, the first electrode AE may be connected to the transistor T-D through a connection electrode CNE disposed in a contact hole CH defined to penetrate the insulating layers VA and PVX. The first electrode AE may be an anode or a cathode. In addition, the first electrode AE may be a pixel electrode. The first electrode AE may be a transmissive electrode, a transflective electrode, or a reflective electrode.

The second electrode CE may face the first electrode AE with a light-emitting structure ST interposed in between. The second electrode CE may be a common electrode. The second electrode CE may be a cathode or an anode, but the embodiment of the inventive concept is not necessarily limited thereto. For example, when the first electrode AE is the anode, the second electrode CE may be the cathode, and when the first electrode AE is the cathode, the second electrode CE may be the anode. The second electrode CE may be a transmissive electrode, a transflective electrode or a reflective electrode.

The display layer DP-ED includes the pixel defining layer PDL. For example, the pixel defining layer PDL may be an organic layer. The pixel defining layer PDL may be made of a polymer resin. For example, the pixel defining layer PDL may include a polyacrylate-based resin, a polyimide-based resin, or another material including polyimide. In addition, the pixel defining layer PDL may further include an inorganic material in addition to the polymer resin. The pixel defining layer PDL may include a light absorbing material or may include a black pigment or a black dye. The pixel defining layer PDL including the black pigment or the black dye may realize a black pixel defining layer. When forming a pixel defining layer PDL, carbon black or the like may be used as a black pigment or black dye, but an embodiment of the inventive concept is not necessarily limited thereto.

In addition, the pixel defining layer PDL may be made of the inorganic material. For example, the pixel defining layer PDL may be formed of inorganic materials such as silicon nitride, silicon oxide, or silicon oxynitride.

In the pixel defining layer PDL, a light-emitting opening OH-ED and an electrode opening OP-PDL are defined. The light-emitting opening OH-ED and the electrode opening OP-PDL may be non-overlapping. The light-emitting opening OH-ED may be defined to overlap the pixel areas PXA1, PXA2, and PXA3, while the electrode opening OP-PDL may be defined to overlap a portion of the non-pixel area NPXA. The electrode opening OP-PDL may be provided in the opening area OPA and may overlap the first opening OP-PVX and the second opening OP-VA. The electrode opening OP-PDL may expose at least a portion of the electrode pattern SE.

The light-emitting opening OH-ED of the pixel defining layer PDL may expose at least a portion of the first electrode AE. In one embodiment, a light-emitting area EA may be defined by the light-emitting opening OH-ED. The light-emitting area EA may refer to areas separated by the pixel defining layer PDL. The light-emitting area EA may be a portion overlapping the pixel area PXA1. In FIGS. 7 and 8, only one light-emitting area EA is shown; however, the light-emitting areas may correspond to each of the first to third pixel areas PXA1, PXA2, and PXA3. In a plan view, a surface area of the pixel area PXA1, which is defined by a division pattern BMP, may be greater than that of the light-emitting area EA, which is defined by the pixel defining layer PDL.

The light-emitting structure ST may be commonly disposed across the pixel areas PXA1, PXA2, and PXA3. Additionally, in the configuration of the light-emitting unit constituting the light-emitting structure ST, the hole transport layer and electron transport layer may be commonly disposed on the entire pixel areas PXA1, PXA2, and PXA3, while the light-emitting layer may be patterned to correspond to each of the pixel areas PXA1, PXA2, and PXA3, and disposed within the light-emitting opening OH-ED.

The light-emitting structure ST may be disposed on the non-pixel area NPXA. However, in the opening area OPA of the non-pixel area NPXA, the light-emitting structure ST may be removed. In the opening area OPA, the light-emitting structure ST may be removed, and the second electrode CE may be connected to the electrode pattern SE. The light-emitting structure ST may be removed by a laser drilling method.

The display layer DP-ED may include an encapsulation layer TFE that protects the light-emitting element OEL. The encapsulation layer TFE may include an organic material or an inorganic material. The encapsulation layer TFE may have a multilayer structure in which inorganic layers and organic layers are alternately stacked. In one embodiment, the encapsulation layer TFE may include a first inorganic layer IOL1, an organic layer OL, and a second inorganic layer IOL2, which are sequentially stacked. However, the layers constituting the encapsulation layer TFE are not necessarily limited thereto. The encapsulation layer TFE may be directly provided on the light-emitting element OEL in a continuous process.

The electrode pattern SE of the display layer DP-ED may be disposed on the same layer as the first electrode AE. The electrode pattern SE may be disposed on the upper insulating layer VA. The electrode pattern SE and the first electrode AE may be provided in the same process step. The electrode pattern SE may be formed of the same material as the first electrode AE.

The light control panel OSL may be disposed on the encapsulation layer TFE. The light control panel OSL may include the light control layer CCL including quantum dots. The light control panel OSL may further include a low-refractive layer LR, a color filter layer CFL, and a base substrate BL, in addition to the light control layer CCL.

The light control layer CCL may include the division pattern BMP and a plurality of light control parts CCP-R, CCP-G, and CCP-B.

The division pattern BMP may serve to separate the plurality of light control parts CCP-R, CCP-G, and CCP-B from each other. The division pattern BMP may include a black component for blocking light.

An opening BW-OH corresponding to the light-emitting opening OH-ED may be defined in the division pattern BMP. In a plan view, the opening BW-OH overlaps the light-emitting opening OH-ED and has a surface area greater than that of the light-emitting opening OH-ED. For example, the opening BW-OH may have a surface area greater than that of the light-emitting area EA defined by the light-emitting opening OH-ED. The light control parts CCP-R, CCP-G, and CCP-B may be disposed inside the opening BW-OH.

In one embodiment, the light control layer CCL may include a first light control part CCP-R corresponding to the first pixel area PXA1, a second light control part CCP-G corresponding to the second pixel area PXA2, and a third light control part CCP-B corresponding to the third pixel area PXA3. The first light control part CCP-R may be a red light control part that emits red light, the second light control part CCP-G may be a green light control part that emits green light. The third light control part CCP-B may be a blue light control part that emits blue light. Alternatively, the third light control part CCP-B may be a transmissive light control part that transmits and emits the source light. At least one of the first to third light control parts CCP-R, CCP-G, and CCP-B of the light control layer CCL may include quantum dots that modify the optical properties of the source light.

In the light control panel OSL according to one embodiment, the base substrate BL may provide a reference surface on which the color filter layer CFL, the low-refractive layer LR, and the light control layer CCL are disposed. The base substrate BL may be a glass substrate, a metal substrate, or a plastic substrate. However, the embodiment is not necessarily limited thereto, and the base substrate BL may be an inorganic layer, an organic layer, or a composite material layer. Also, the base substrate BL may be omitted in one embodiment.

In one embodiment, the light control layer CCL may include barrier layers CAP1 and CAP2. The barrier layers CAP1 and CAP2 may function to block the penetration of moisture and/or oxygen (hereinafter, referred to as “moisture/oxygen”) and to adjust the refractive index, thereby enhancing the optical properties of the light control panel OSL. Each of the first barrier layer CAP1 and the second barrier layer CAP2 may include the inorganic material.

The light control panel OSL may further include the color filter layer CFL disposed on the light control layer CCL. The color filter layer CFL may include at least one of the color filters CF1, CF2, or CF3. The color filter may transmit light having a specific wavelength range and block light other than the corresponding wavelength range. In one embodiment, the first color filter CF1 may be a red filter that transmits red light, the second color filter CF2 may be a green filter that transmits green light, and the third color filter CF3 may be a blue filter that transmits blue light.

Each of the color filters CF1, CF2, and CF3 may include a polymer photosensitive resin and a colorant. The colorant may include a pigment or a dye. The first color filter CF1 may include a red pigment or red dye, the second color filter CF2 may include a green pigment or green dye, and the third color filter CF3 may include a blue pigment or blue dye. In one embodiment, the third color filter CF3 may not include any pigment or dye.

Each of the first to third color filters CF1, CF2, and CF3 may correspond to the first pixel area PXA1, the second pixel area PXA2, and the third pixel area PXA3, respectively. Additionally, each of the first to third color filters CF1, CF2, and CF3 may overlap each of the first to third light control parts CCP-R, CCP-G, and CCP-B, respectively.

Referring to FIG. 7, a plurality of color filters CF1, CF2, and CF3, which transmit different types of light may overlap with each other, corresponding to the non-pixel area NPXA. The plurality of color filters CF1, CF2, and CF3 may overlap each other in the third direction DR3, which is the thickness direction, corresponding to the non-pixel area NPXA, thereby distinguishing the boundaries between adjacent pixel areas PXA1, PXA2, and PXA3. The color filter layer CFL may include a light-blocking part to distinguish the boundaries between the adjacent color filters CF1, CF2, and CF3. The light-blocking part may be a blue filter or may include an organic light-blocking material including a black pigment or black dye or an inorganic light-blocking material.

In one embodiment, the light control panel OSL may further include the low-refractive layer LR. The low-refractive layer LR may be disposed between the light control parts CCP-R, CCP-G, and CCP-B and the color filters CF1, CF2, and CF3, and may function as an optical functional layer that enhances the light extraction efficiency of the light emitted from the light control layer CCL or prevents reflected light from entering the light control layer CCL. The low-refractive layer LR may be a layer with a relatively lower refractive index compared to a layer adjacent thereto.

In one embodiment, the light control panel OSL may further include the base substrate BL disposed on the color filter layer CFL. The base substrate BL may provide a reference surface on which the color filter layer CFL, the low-refractive layer LR, and the light control layer CCL are disposed. The base substrate BL may be an inorganic layer, an organic layer, or a composite material layer. Also, the base substrate BL may be omitted in one embodiment.

In the display panel DP, according to one embodiment, the first opening OP-PVX defined in the lower insulating layer PVX, the second opening OP-VA defined in the upper insulating layer VA, and the electrode opening OP-PDL defined in the pixel defining layer PDL may provide a contact opening area OH-ECA. In the contact opening area OH-ECA, the electrode pattern SE may be disposed directly on the power line EL, and the second electrode CE may be disposed directly on the electrode pattern SE. In the contact opening area OH-ECA, a portion in which the power line EL, the electrode pattern SE, and the second electrode CE overlap and connect with each other may be defined.

Compared to a typical display panel, which require two separate opening areas, for the contact between the power line and the electrode pattern and for the contact between the electrode pattern and the second electrode, in the display panel, according to one embodiment, the power line EL, the electrode pattern SE, the second electrode CE may be connected to each other in one contact opening area OH-ECA, thereby reducing a surface area of the opening area required for electrode connection in the display panel DP. Accordingly, even when implementing a high-resolution display panel DP, the contact opening area OH-ECA may be effectively disposed within the limited surface area of the non-pixel area NPXA, resulting in excellent reliability characteristics.

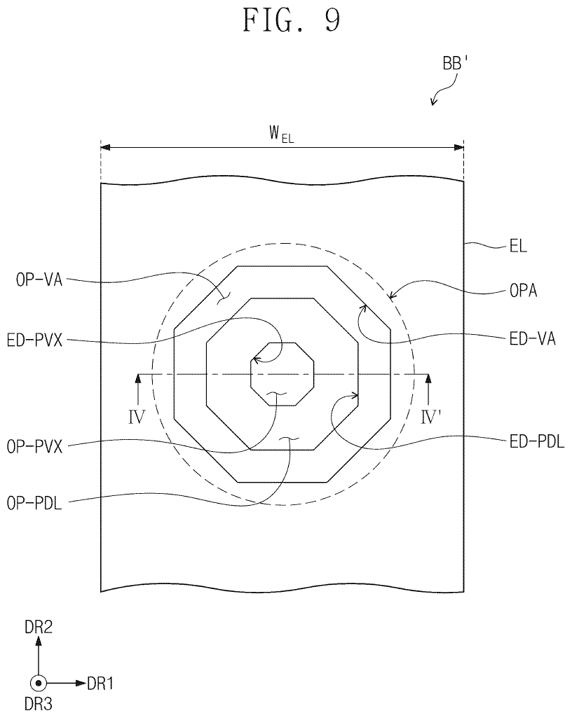

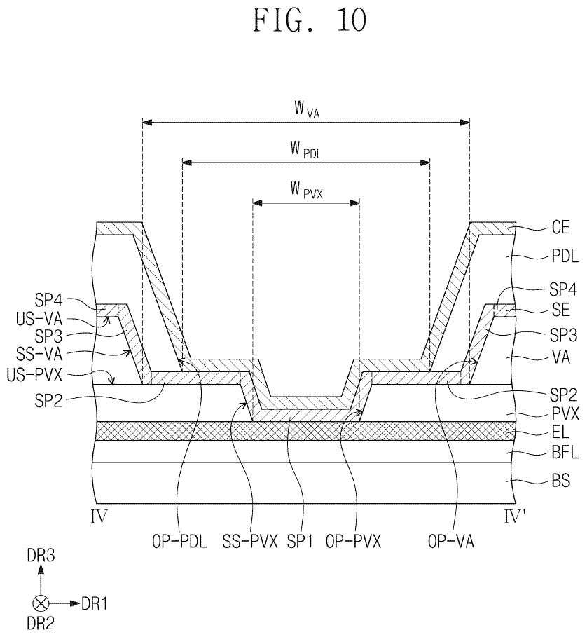

FIG. 9 is an enlarged plan view illustrating a portion of the display panel according to one embodiment, and FIG. 10 is an enlarged cross-sectional view illustrating a portion of the display panel according to one embodiment. FIG. 9 is a plan view of a portion corresponding to area BB′ of FIG. 6, and FIG. 10 is a cross-sectional view of a portion corresponding to line IV-IV′ of FIG. 9.

The opening area OPA may overlap the power line EL. In a plan view, the size of the opening area OPA in the first direction DR1 may be smaller than a width or longest dimension WEL of the power line EL in the first direction DR1. As a result, the entire opening area OPA may overlap the power line EL.

Referring to FIGS. 9 and 10, the opening area OPA may be a portion including the first opening OP-PVX, the second opening OP-VA, and the electrode opening OP-PDL, which are defined in an overlapping manner.

In a plan view, the second opening OP-VA may have a surface area that is greater than that of the electrode opening OP-PDL. In a plan view, an edge ED-VA of the upper insulating layer that defines the second opening OP-VA, may surround an edge ED-PDL of the pixel defining layer that defines the electrode opening OP-PDL. Additionally, in a cross-sectional view perpendicular to the base layer BS, a width or longest dimension WVA of the second opening OP-VA defined in the upper insulating layer VA may be greater than a width or longest dimension WPDL of the electrode opening OP-PDL defined in the pixel defining layer PDL. The pixel defining layer PDL may surround a side surface SS-VA of the upper insulating layer VA, which defines the second opening OP-VA, thereby protecting a portion of the upper insulating layer VA that defines the second opening OP-VA.

In one embodiment, the electrode pattern SE may be connected to the power line EL in the first opening OP-PVX, and the electrode pattern SE may be extended from the first opening OP-PVX onto the side surface SS-VA and a top surface US-VA of the upper insulating layer that defines the second opening OP-VA. The pixel defining layer PDL, which defines the electrode opening OP-PDL, may cover the electrode pattern SE that extends along the side surface SS-VA of the upper insulating layer defining the second opening OP-VA.

Referring to FIGS. 9 and 10, in a plan view, the surface area of the first opening OP-PVX may be smaller than that of the electrode opening OP-PDL. In a plan view, the edge ED-PDL of the pixel defining layer that defines the electrode opening OP-PDL may surround the edge ED-PVX of the lower insulating layer that defines the first opening OP-PVX. In addition, in a cross-sectional view perpendicular to the base layer BS, the width or longest dimension WPVX of the first opening OP-PVX defined in the lower insulating layer PVX may be smaller than the width or longest dimension WPDL of the electrode opening OP-PDL defined in the pixel defining layer PDL.

The electrode pattern SE may follow a shape of each of the first opening OP-PVX, the lower insulating layer PVX, the second opening OP-VA, and the upper insulating layer VA.

The electrode pattern SE may include a first portion SP1 disposed in the first opening OP-PVX, a second portion SP2 extending from the first portion SP1 and disposed on a top surface US-PVX of the lower insulating layer, a third portion SP3 extending from the second portion SP2 and disposed on the side surface SS-VA of the upper insulating layer defining the second opening OP-VA, and a fourth portion SP4 extending from the third portion SP3 and disposed on the top surface US-VA of the upper insulating layer.

A portion of the electrode pattern SE may be covered by the pixel defining layer PDL. Referring to FIG. 10, the third portion SP3, the fourth portion SP4, and a portion of the second portion SP2 of the electrode pattern SE may be covered by the pixel defining layer PDL. Accordingly, even when a portion of the light-emitting structure ST (see FIG. 8) is removed by a laser drilling process, a portion of the exposed electrode pattern SE may be protected by the pixel defining layer PDL.

In one embodiment, the second electrode CE may extend from the pixel areas PXA1, PXA2, and PXA3 (see FIG. 7) to the opening area OPA (see FIG. 8) and may be disposed as a common layer across the entire non-pixel area NPXA (see FIG. 8) that includes both the pixel areas PXA1, PXA2, and PXA3 (see FIG. 7) and the opening area OPA (see FIG. 8).

The second electrode CE may be directly connected to at least a portion of the electrode pattern SE in the opening area OPA. Referring to FIG. 10, in one embodiment, the second electrode CE may be in direct contact with the first portion SP1 of the electrode pattern SE and a portion of the second portion SP2 adjacent to the first portion SP1. The second electrode CE may follow a shape of each of the first opening OP-PVX, the lower insulating layer PVX, the electrode opening OP-PDL, and the pixel defining layer PDL in the opening area OPA.

In the embodiment shown in FIGS. 9 and 10, a surface area of a portion in which the power line EL, the electrode pattern SE, and the second electrode CE overlap to be in direct contact with each other may correspond to a surface area of the first opening OP-PVX, in a plan view. As a result, compared to a typical display panel, which is manufactured by separately defining areas for the connection of the power line and the electrode pattern, and for the connection of the electrode pattern and the second electrode, the display panel according to one embodiment may reduce the area required for a connection structure of the electrode pattern introduced to reduce voltage drop. For example, the display panel according to one embodiment may effectively define the contact opening area OH-ECA (see FIG. 8) within a narrow space, thereby enabling high-resolution implementation.

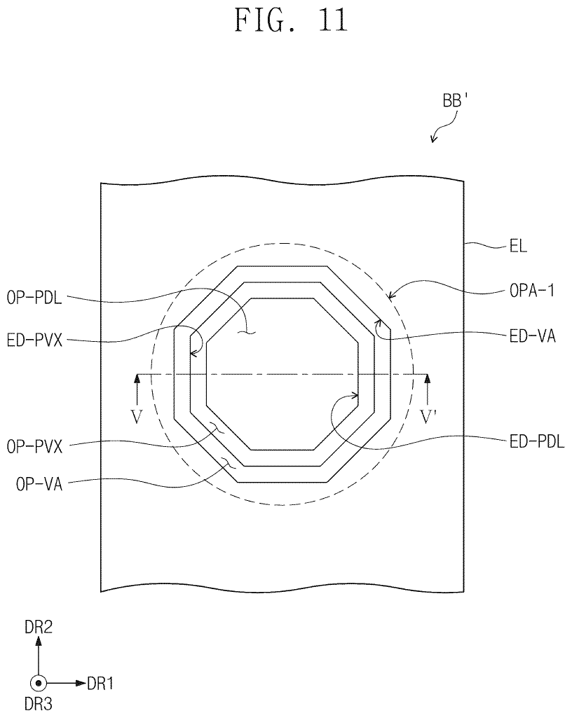

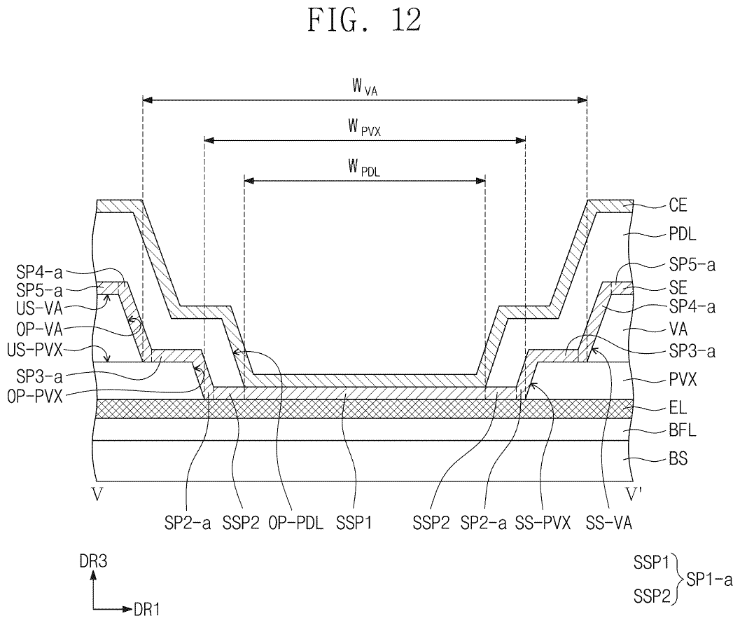

FIG. 11 is an enlarged plan view illustrating a portion of the display panel according to one embodiment, and FIG. 12 is an enlarged cross-sectional view illustrating a portion of the display panel according to one embodiment. FIG. 11 may be a plan view of the portion corresponding to area BB′ of FIG. 6. FIG. 12 may be a cross-sectional view of the portion corresponding to line V-V′ of FIG. 11. The display panel, according to one embodiment described with reference to FIGS. 11 and 12, differs in the size of the first opening OP-PVX and the arrangement of the electrode pattern SE and the second electrode CE, compared to the display panel according to one embodiment described with reference to FIGS. 8 to 10.

Referring to FIG. 11, an opening area OPA-1 may overlap the power line EL. In a plan view, the opening area OPA-1 may overlap entirely within the power line EL.

Referring to FIGS. 11 and 12, the opening area OPA-1 may be a portion that includes the first opening OP-PVX, the second opening OP-VA, and the electrode opening OP-PDL, which are defined as overlapping with each other.

In a plan view, the second opening OP-VA may have a surface area greater than that of the electrode opening OP-PDL. In a plan view, an edge ED-VA of the upper insulating layer that defines the second opening OP-VA, may surround an edge ED-PDL of the pixel defining layer that defines the electrode opening OP-PDL. Additionally, in a cross-sectional view perpendicular to the base layer BS, a width or longest dimension WVA of the second opening OP-VA defined in the upper insulating layer VA may be greater than a width or longest dimension WPDL of the electrode opening OP-PDL defined in the pixel defining layer PDL.

Additionally, in the embodiment shown in FIGS. 11 and 12, the surface area of the first opening OP-PVX in a plan view may be greater than that of the electrode opening OP-PDL but smaller than that of the second opening OP-VA. In a plan view, the edge ED-PVX of the lower insulating layer that defines the first opening OP-PVX may surround the edge ED-PDL of the pixel defining layer that defines the electrode opening OP-PDL. Moreover, the edge ED-VA of the upper insulating layer that defines the second opening OP-VA may surround the edge ED-PVX of the lower insulating layer. In a cross-sectional view perpendicular to the base layer BS, the width or longest dimension WPVX of the first opening OP-PVX defined in the lower insulating layer PVX may be greater than the width or longest dimension WPDL of the electrode opening OP-PDL defined in the pixel defining layer PDL, but smaller than the width or longest dimension WVA of the second opening OP-VA defined in the upper insulating layer VA.

Referring to FIGS. 11 and 12, in one embodiment, the pixel defining layer PDL may surround the side surface SS-VA of the upper insulating layer that defines the second opening OP-VA and the side surface SS-PVX of the lower insulating layer that defines the first opening OP-PVX. Accordingly, a portion of the upper insulating layer VA that defines the second opening OP-VA and a portion of the lower insulating layer PVX that defines the first opening OP-PVX may be protected by the pixel defining layer PDL.

In one embodiment, the electrode pattern SE may be connected to the power line EL in the first opening OP-PVX and may be connected to the second electrode CE in the electrode opening OP-PDL. The electrode pattern SE may extend from the first opening OP-PVX onto the side surface SS-VA of the upper insulating layer that defines the second opening OP-VA and onto the top surface US-VA of the upper insulating layer. The pixel defining layer PDL, which defines the electrode opening OP-PDL, may cover the electrode pattern SE that extends along the side surface SS-PVX of the lower insulating layer defining the first opening OP-PVX and along the side surface SS-VA of the upper insulating layer defining the second opening OP-VA.

The electrode pattern SE may follow a shape of each of the first opening OP-PVX, the lower insulating layer PVX, the second opening OP-VA, and the upper insulating layer VA. The pixel defining layer PDL may follow a shape of each of the first opening OP-PVX, the lower insulating layer PVX, the second opening OP-VA, and the upper insulating layer VA on an inner side of both the first opening OP-PVX and the second opening OP-VA. The second electrode CE may be connected to the electrode pattern SE on the inner side of the electrode opening OP-PDL and may follow the shape of the pixel defining layer PDL.

Referring to FIG. 12, in one embodiment, the electrode pattern SE may include a first portion SP1-a in direct contact with the power line EL in the first opening OP-PVX, a second portion SP2-a extending from the first portion SP1-a and disposed on the side surface SS-PVX of the lower insulating layer, a third portion SP3-a extending from the second portion SP2-a and disposed on the top surface US-PVX of the lower insulating layer, a fourth portion SP4-a extending from the third portion SP3-a and disposed on the side surface SS-VA of the upper insulating layer defining the second opening OP-VA, and a fifth portion SP5-a extending from the fourth portion SP4-a and disposed on the top surface US-VA of the upper insulating layer. The first portion SP1-a of the electrode pattern SE may include a first sub portion SSP1, which is connected to both the power line EL and the second electrode CE, and a second sub-portion SSP2, which is connected to the power line EL but is separated from the second electrode CE by the pixel defining layer PDL.

The second to fifth portions SP2-a, SP3-a, SP4-a, and SP5-a of the electrode pattern SE, as well as a portion SSP2 of the first portion SP1-a, may be covered by the pixel defining layer PDL. Portions of the electrode pattern SE covered by the pixel defining layer PDL may not be connected to the second electrode CE. The second electrode CE may be in direct contact with a portion SSP1 of the first portion SP1-a of the electrode pattern SE that is not covered by the pixel defining layer PDL.

Referring to FIG. 12, as the second sub-portion SSP2, and the second to fifth portions SP2-a, SP3-a, SP4-a, and SP5-a of the electrode pattern SE are covered by the pixel defining layer PDL, even when a portion of the light-emitting structure ST (see FIG. 8) is removed through a laser drilling process, the exposed portion of the electrode pattern SE may be protected by the pixel defining layer PDL.

The second electrode CE may be directly connected to at least a portion of the electrode pattern SE in the opening area OPA-1. Referring to FIG. 12, in one embodiment, the second electrode CE may be in direct contact with the first sub-portion SSP1 of the electrode pattern SE. The second electrode CE may be disposed in the opening area OPA-1, spaced apart from the electrode pattern SE, including the second sub-portion SSP2 and the second to fifth parts SP2-a, SP3-a, SP4-a, and SP5-a, with the pixel defining layer PDL interposed in between.

In one embodiment shown in FIGS. 11 and 12, a surface area of the portion in which the power line EL, the electrode pattern SE, and the second electrode CE overlap to be in direct contact with each other may correspond to that of the electrode opening OP-PDL, in a plan view. As a result, compared to a typical display panel, which is manufactured by separately defining areas for the connection of the power line and the electrode pattern, and for the connection of the electrode pattern and the second electrode, the display panel according to one embodiment may reduce the area required for a connection structure of the electrode pattern introduced to reduce voltage drop. For example, the display panel according to one embodiment may implement high resolution by effectively defining the contact opening area OH-ECA (see FIG. 8) within a narrow space.

Table 1 shows a comparison of the surface area of the contact opening area between a typical display panel and the display panel according to one embodiment. In Table 1, Comparative Example refers to a typical display panel having a two-hole structure in which the opening area where the power line and electrode pattern are connected to each other is separated from the opening area where the electrode pattern and the second electrode are connected to each other. Additionally, in Table 1, Embodiment 1 pertains to the display panel having the contact opening area shown in FIG. 10, and Embodiment 2 pertains to the display panel having the contact opening area including the structure shown in FIG. 12. In Table 1, the surface area corresponds to a planar surface area of the electrode pattern exposed in the opening area (or contact opening area). Embodiments 1 and 2 are presented as relative values, with the area of Comparative Example 1 set at 100%.

TABLE 1

| | Comparative | | |
|---|---|---|---|
| Classification | Example | Embodiment 1 | Embodiment 2 |
| Surface area (%) | 100 | 57 | 65 |

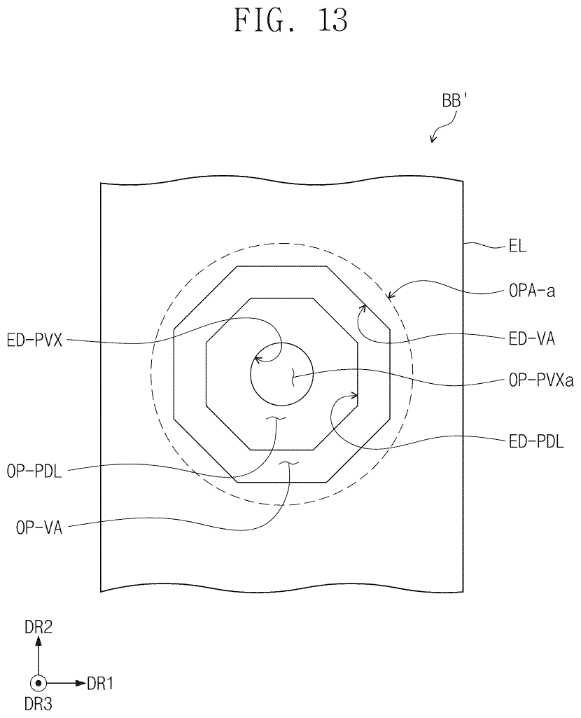

Referring to the results of Table 1, in Embodiments 1 and 2, the surface area of the opening area defined by the laser drilling method and the corresponding exposed surface area of the electrode pattern are significantly reduced compared to the Comparative Example. As a result, in the embodiment, a one-hole structure is employed instead of the two-hole structure, allowing the connection of the power line, the electrode pattern, and the second electrode in a single contact opening area. Therefore, the laser drilling process may be more easily carried out. Additionally, the surface area required for defining the opening area is also reduced, making it easier to introduce the contact opening area even in high-resolution displays. Consequently, issues related to voltage drop may be mitigated, leading to improved reliability characteristics of the display panel. FIG. 13 is a plan view illustrating a portion of the display panel according to one embodiment. FIG. 13 may be a plan view of the portion corresponding to area BB′ of FIG. 6. Compared to FIG. 9, FIG. 13 shows a difference in a planar shape of the first opening OP-PVXa provided in the opening area OPA-a. In FIGS. 9 and 11, the first opening OP-PVX, the second opening OP-VA, and the electrode opening OP-PDL are illustrated as having an octagonal shape in a plan view, but this is merely an example and the shapes of the openings in a plan view are not necessarily limited thereto.

In FIG. 13, a first opening OP-PVXa may have a circular shape in a plan view. In the case of the first opening OP-PVXa, which is patterned using a photomask, introducing a concave-convex structure or a slit structure into the photomask may induce the diffraction of light during the exposure process, thereby facilitating the patterning of the first opening OP-PVXa. The first opening OP-PVXa, which is patterned using a mask with a concave-convex or slit structure, may have a substantially circular shape, in a plan view.

FIG. 13 shows an example of the first opening OP-PVXa having a circular shape in a plan view; however, the embodiment is not necessarily limited thereto, and a shape of each of the second opening OP-VA and the electrode opening OP-PDL may also be modified.

The display panel and the electronic device according to one embodiment may include the contact opening area defined by the overlapping of the first opening in the lower insulating layer, the second opening in the upper insulating layer, and the electrode opening in the pixel defining layer. In the contact opening area, corresponding to a single hole area, the power line, the electrode pattern, and the second electrode, which is the common electrode, are connected to each other, minimizing the number and surface area of the hole areas required for improving electrical characteristics in the display panel and the electronic device, thereby enabling high-resolution implementation. Additionally, in the display panel and the electronic device including the same, the process for defining the hole area to enhance electrical characteristics may be reduced, thereby increasing production efficiency during the manufacturing of the display panel and the electronic device.

Furthermore, by making the size of the electrode opening defined in the pixel defining layer smaller than that of the opening defined in the upper insulating layer, the pixel defining layer may cover a portion of the opening in the upper insulating layer, thereby protecting the upper insulating layer and components of other circuit layer and display layer, during processes such as laser drilling. Accordingly, the display panel and the electronic device including the same according to one embodiment may have excellent reliability characteristics.

The display panel and the electronic device according to one embodiment may minimize the surface area required for the placement of the contact opening area by allowing the power line, the electrode pattern, and the second electrode to be electrically connected within a single contact opening area defined by the overlapping of the openings, which are defined respectively in the lower insulating layer, the upper insulating layer, and the pixel defining layer.

In one embodiment, the display panel and the electronic device including the same may minimize the non-pixel area by disposing contact structures for improving voltage drop within a single contact opening area, enabling high resolution and exhibiting excellent electrical characteristics and reliability.

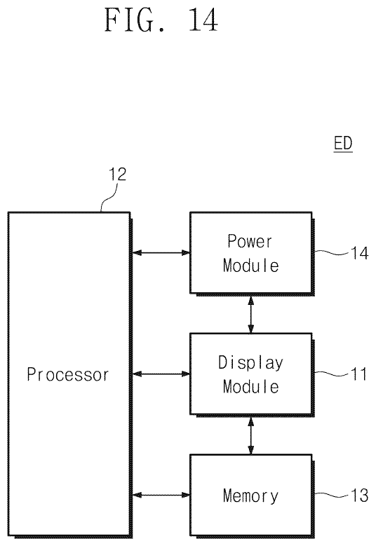

FIG. 14 is a block diagram of an electronic device according to an embodiment. Referring to FIG. 14, an electronic device ED according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen. The display module 11 may include a display panel which displays an image.

The power module 14 may include a power supply module such as a power adapter or a battery device, and a power conversion module which converts the power supplied by the power supply module and generates power necessary for an operation of the electronic device ED.

At least one of the components of the electronic device ED described above may be included in a display device including the display panel according to an embodiment, described later. In addition, some of individual modules included as functional in one module may be included in the display device, and others may be provided separately from the display device. For example, the display device may include the display module 11, and the processor 12, the memory 13, and the power module 14 may be provided not in the display device but in another type of device in the electronic device ED.

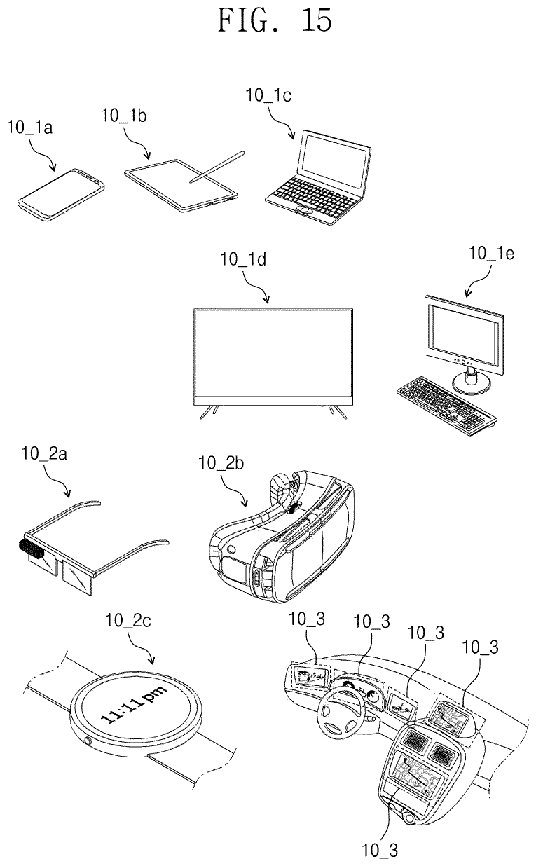

FIG. 15 illustrates schematic views of electronic devices according to various embodiments.

Referring to FIG. 15, various electronic devices including a display device according to an embodiment may include not only an electronic device for image display, e.g., a smartphone 10_1a, a tablet computer (PC) 10_1b, a laptop computer 10_1c, TV 10_1d, and a monitor for a desk computer 10_1e, but also a wearable electronic device including a display module, e.g., smart glasses 10_2a, a head mounted display 10_2b, and a smart watch 10_2c, and an electronic device for vehicle 10_3 including a display module, e.g., a vehicle instrument panel, a center fascia, a center information display (CID) disposed on a dashboard, and a room mirror display.

Although the present disclosure has been described with reference to the embodiments, it will be understood that various changes and modifications of the present disclosure may be made by one ordinary skilled in the art or one having ordinary knowledge in the art without departing from the spirit and technical field of the disclosure.

What is claimed is:

1. A display panel comprising:
a base layer;
a circuit layer disposed on the base layer, the circuit layer comprising:
a transistor;
a power line receiving a power supply voltage;
a lower insulating layer disposed on the power line and including a first opening through which the power line is exposed; and
an upper insulating layer disposed on the lower insulating layer and including a second opening overlapping the first opening; and
a display layer disposed on the circuit layer, the display layer comprising:
a pixel defining layer including an electrode opening that overlaps the first and second openings, and a light-emitting opening that does not overlap the electrode opening;
a light-emitting element corresponding to the light-emitting opening; and
an electrode pattern corresponding to the electrode opening,
wherein the light-emitting element comprises a first electrode disposed in the light-emitting opening, a light-emitting structure disposed on the first electrode, and a second electrode disposed on the light-emitting structure,
wherein the power line, the electrode pattern, and the second electrode are electrically connected to each other in a contact opening area in which the first opening, the second opening, and the electrode opening overlap, and
wherein a longest dimension of the second opening in a first direction is greater than a longest dimension of the electrode opening in the first direction.

2. The display panel of claim 1, wherein, in the contact opening area, the electrode pattern is disposed directly on the power line, and the second electrode is disposed directly on the electrode pattern.

3. The display panel of claim 1, wherein, in a plan view, an edge of the upper insulating layer that defines the second opening surrounds an edge of the pixel defining layer that defines the electrode opening.

4. The display panel of claim 1, wherein the electrode pattern is electrically connected to the power line in the first opening and extends from the first opening toward a side surface and a top surface of the upper insulating layer that defines the second opening.

5. The display panel of claim 4, wherein the pixel defining layer that defines the electrode opening covers the electrode pattern extending from the side surface of the upper insulating layer that defines the second opening.

6. The display panel of claim 1, wherein a longest dimension of the first opening in the first direction is less than a longest dimension of the electrode opening in the first direction.

7. The display panel of claim 6, wherein the electrode pattern comprises:
a first portion disposed in the first opening;
a second portion extending from the first portion and disposed on a top surface of the lower insulating layer;
a third portion extending from the second portion and disposed on a side surface of the upper insulating layer that defines the second opening; and
a fourth portion extending from the third portion and disposed on a top surface of the upper insulating layer,
wherein the third portion, the fourth portion, and at least a part of the second portion are covered by the pixel defining layer.

8. The display panel of claim 7, wherein the second electrode is in direct contact with the first portion of the electrode pattern and at least part of the second portion that is adjacent to the first portion of the electrode pattern.

9. The display panel of claim 1, wherein a longest dimension of the first opening in the first direction is greater than a longest dimension of the electrode opening in the first direction and is also smaller than a longest dimension of the second opening in the first direction.

10. The display panel of claim 9, wherein the electrode pattern comprises:
a first portion that is in direct contact with the power line in the first opening;
a second portion extending from the first portion and disposed on a side surface of the lower insulating layer;
a third portion extending from the second portion and disposed on a top surface of the lower insulating layer;
a fourth portion extending from the third portion and disposed on a side surface of the upper insulating layer that defines the second opening; and
a fifth portion extending from the fourth portion and disposed on a top surface of the upper insulating layer,
wherein the second to fifth portions and at least a part of the first portion are covered by the pixel defining layer.

11. The display panel of claim 10, wherein the second electrode is in direct contact with a part of the first portion, which is not covered by the pixel defining layer.

12. The display panel of claim 1, wherein the electrode pattern is disposed on a same layer as the first electrode, and
wherein the electrode pattern and the first electrode include a same material.

13. The display panel of claim 1, wherein the transistor comprises a semiconductor pattern, and
wherein the semiconductor pattern and the power line are disposed on a same layer.

14. The display panel of claim 1, wherein the lower insulating layer is an inorganic layer, and
wherein the upper insulating layer is an organic layer.

15. The display panel of claim 1, wherein the lower insulating layer comprises silicon nitride, and
wherein the upper insulating layer comprises polyimide.

16. An electronic device comprising:
a display module divided into a plurality of pixel areas, that each emit light having different wavelength ranges, and a non-pixel area, that surrounds the plurality of pixel areas, the display module comprising a display panel and a light control panel disposed on the display panel; and
a housing accommodating the display module,
wherein the display panel comprises:
a base layer;
a circuit layer, comprising:
a power line disposed on the base layer in the non-pixel area;
a lower insulating layer disposed on the power line and including a first opening, through which the power line is exposed; and
an upper insulating layer disposed on the lower insulating layer and including a second opening overlapping the first opening; and
a display layer disposed on the circuit layer, the display layer comprising:
a pixel defining layer including an electrode opening that entirely overlaps the second opening and a light-emitting opening that does not overlap the electrode opening;
a light-emitting element corresponding to the light-emitting opening; and
an electrode pattern corresponding to the electrode opening,
wherein the light-emitting element comprises a first electrode disposed in the light-emitting opening, a light-emitting structure disposed on the first electrode, and a second electrode disposed on the light-emitting structure,
wherein the power line, the electrode pattern, and the second electrode are electrically connected to each other in a contact opening area where the first opening, the second opening, and the electrode opening overlap one another, and
wherein, in a plan view, a surface area of the second opening is greater than a surface area of the electrode opening.

17. The electronic device of claim 16, wherein, in the plan view, an edge of the upper insulating layer that includes the second opening surrounds an edge of the pixel defining layer that includes the electrode opening.

18. The electronic device of claim 16, wherein the power line extends in a first direction on the base layer, and
wherein a plurality of contact opening areas overlap the power line.

19. The electronic device of claim 18, wherein, in each of the plurality of contact opening areas, the electrode pattern is disposed directly on the power line, and
wherein the second electrode is disposed directly on the electrode pattern.

20. The electronic device of claim 16, wherein the electrode pattern extends from the first opening toward a side surface and a top surface of the upper insulating layer that defines the second opening, and
wherein the pixel defining layer that defines the electrode opening covers the electrode pattern extending from the side surface of the upper insulating layer that defines the second opening.
